(19) United States
(12) Patent Application Publication
(10) Pub. No.: US 2026/0123158 A1
(43) Pub. Date: Apr. 30, 2026

(54) DISPLAY DEVICE AND METHOD OF MANUFACTURING THE DISPLAY DEVICE

(71) Applicant: SAMSUNG ELECTRONICS CO., LTD., Suwon-si (KR)

(72) Inventors: Sunil Kim, Suwon-si (KR); Junhee Choi, Suwon-si (KR); Kyungwook Hwang, Suwon-si (KR)

(73) Assignee: SAMSUNG ELECTRONICS CO., LTD., Suwon-si (KR)

(21) Appl. No.: 19/249,533

(22) Filed: Jun. 25, 2025

(30) Foreign Application Priority Data
Oct. 31, 2024 (KR) 10-2024-0152961

(51) Int. Cl. H10H 29/855; G02B 1/04; G02B 5/32; H10H 29/01

(52) U.S. Cl. CPC H10H 29/855; G02B 1/041; G02B 5/32; H10H 29/0363

(57) ABSTRACT

A display device includes: a first light-emitting element; a second light-emitting element on the first light-emitting element; and a third light-emitting element on the second light-emitting element; a first lens provided below the first light-emitting element, wherein each of the first light-emitting element, the second light-emitting element, and the third light-emitting element includes a first semiconductor layer of a first conductive type, an active layer, and a second semiconductor layer of a second conductive type that are sequentially stacked, and wherein the first lens includes: a first interference pattern configured to reflect first incident light, that diverges from a first focal point outside the first lens and enters the first lens, to form parallel light; and a second interference pattern configured to reflect second incident light, that diverges from a second focal point outside the first lens and enters the first lens, to form parallel light.

### CROSS-REFERENCE TO RELATED APPLICATION

This application claims priority to Korean Patent Application No. 10-2024-0152961, filed on October 31, 2024, in the Korean Intellectual Property Office, the disclosure of which is incorporated by reference herein in its entirety.

### BACKGROUND

### 1. Field

The disclosure relates to a display device and a method of manufacturing the display device.

### 2. Description of Related Art

In a monolithic light source, the light sources may be arranged horizontally or vertically. The horizontal arrangement involves placing red-green-blue (RGB) light sources horizontally, which enables implementation of a structure that may enhance the light extraction efficiency (LEE) of each RGB light source, but faces limitations in resolution.

On the other hand, the vertical arrangement is implemented by stacking RGB light sources vertically, and offers advantages of no loss of resolution and relatively low driving current density, but reduces the light extraction efficiency due to differences in distance from the lens according to the stacking of the RGB light sources. Therefore, a manufacturing process for the vertical stacking, with enhanced light extraction efficiency is required.

### SUMMARY

Provided are a display device with enhanced light extraction efficiency and a method of manufacturing the display device.

Additional aspects will be set forth in part in the description which follows and, in part, will be apparent from the description, or may be learned by practice of the presented embodiments of the disclosure.

According to an aspect of the disclosure, a display device includes: a first light-emitting element; a second light-emitting element on the first light-emitting element; and a third light-emitting element on the second light-emitting element; a first lens provided below the first light-emitting element, wherein each of the first light-emitting element, the second light-emitting element, and the third light-emitting element includes a first semiconductor layer of a first conductive type, an active layer, and a second semiconductor layer of a second conductive type that are sequentially stacked, and wherein the first lens includes: a first interference pattern configured to reflect first incident light, that diverges from a first focal point outside the first lens and enters the first lens, to form parallel light; and a second interference pattern configured to reflect second incident light, that diverges from a second focal point outside the first lens and enters the first lens, to form parallel light.

The first lens may further include a third interference pattern configured to reflect third incident light, that diverges from a third focal point outside the first lens and enters the first lens, to form parallel light.

The first lens may include a photopolymer.

The photopolymer may include a first monomer responsive to red light, a second monomer responsive to green light, and a third monomer responsive to blue light.

The first lens may include a holographic lens.

A thickness of the first lens may be 2 μm to 10 μm.

The display device may further include a second lens on the third light-emitting element.

The second lens may be configured to reduce angular distribution of light reflected by the first lens.

The display device may further include a backplane substrate provided below the first lens and including at least one driving element.

According to an aspect of the disclosure, a display device includes: a third light-emitting element; a second light-emitting element on the third light-emitting element; and a first light-emitting element on the second light-emitting element; and a first lens provided above the first light-emitting element; wherein each of the first light-emitting element, the second light-emitting element, and the third light-emitting element may include a first semiconductor layer of a first conductive type, an active layer, and a second semiconductor layer of a second conductive type that are sequentially stacked, wherein the first lens includes: a first interference pattern configured to diffract first incident light, that diverges from a first focal point outside the first lens and enters the first lens, to form parallel light; and a second interference pattern configured to diffract second incident light, that diverges from a second focal point outside the first lens and enters the first lens, to form parallel light.

The first lens may further include a third interference pattern configured to diffract third incident light, that diverges from a third focal point outside the first lens and enters the first lens, to form parallel light.

The first lens may include a photopolymer.

The photopolymer may include a first monomer responsive to red light, a second monomer responsive to green light, and a third monomer responsive to blue light.

The first lens may include a holographic lens.

A thickness of the first lens may be 2 μm to 10 μm.

The display device may include a second lens on the first lens.

The second lens may be configured to reduce angular distribution of light diffracted by the first lens.

The display device may further include a backplane substrate on the third light-emitting element and including at least one driving element.

According to an aspect of the disclosure, a method of manufacturing a display device, includes: forming, in a lens, a first interference pattern configured to reflect first incident light, that diverges from a first focal point outside the lens and enters the lens, to form parallel light; forming, in the lens, a second interference pattern configured to reflect second incident light, that diverges from a second focal point outside the lens and enters the lens, to form parallel light; providing the lens on a backplane substrate; providing a first light-emitting element on the lens; providing a second light-emitting element on the first light-emitting element; and providing a third light-emitting element on the second light-emitting element.

The method may further include forming, in the lens, a third interference pattern configured to reflect third incident light, that diverges from a third focal point outside the lens and enters the lens, to form parallel light.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a cross-sectional view showing a display device according to one or more embodiments;

FIG. 2 is a cross-sectional view showing a display device according to one or more embodiments;

FIG. 3 is a cross-sectional view showing a display device according to one or more embodiments;

FIG. 4 is a cross-sectional view showing a display device according to one or more embodiments;

FIGS. 5A, 5B, 5C, 5D, and 5E are diagrams showing a method of manufacturing a display device, according to one or more embodiments;

FIGS. 6A, 6B, and 6C are cross-sectional views showing a method of manufacturing a lens, according to one or more embodiments;

FIG. 7 illustrates an example in which a display device according to one or more embodiments is applied to a mobile device;

FIG. 8 illustrates an example in which a display device according to one or more embodiments is applied to a vehicle display device;

FIG. 9 illustrates an example in which a display device according to one or more embodiments is applied to an augmented reality glass or a virtual reality glass;

FIG. 10 illustrates an example in which a display device according to one or more embodiments is applied to signage; and

FIG. 11 illustrates an example in which a display device according to one or more embodiments is applied to a wearable display.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, with reference to the attached drawings, display devices and methods of manufacturing the display devices according to various embodiments are described in detail. In the drawings below, the same reference numerals denote the same components, and the size of each component in the drawings may be exaggerated for clarity and ease of explanation. In addition, the embodiments described below are merely examples, and various modifications are possible from these embodiments.

Hereinafter, the terms “upper” and “on” may include not only things that are directly above and in contact, but also things that are above in a non-contact manner. Singular expressions shall include plural expressions unless the context clearly indicates otherwise. Additionally, when a part is said to “comprise” a component, this does not mean that it excludes other components, but rather that it may include other components, unless otherwise specifically stated.

The definite article “the” and similar referential terms may denote both singular and plural forms. Unless the steps of a method are explicitly described in a particular order or in a different order, these steps may be performed in any suitable order and are not necessarily limited to the order described.

The connections or lack of connections of lines between components shown in the drawings are example representations of functional connections and/or physical or circuit connections, which may be represented by various alternative or additional functional, physical, or circuit connections in the actual device.

Any use of examples or example terms is merely intended to elaborate technical ideas and is not intended to limit the scope of the disclosure unless otherwise defined by the claims.

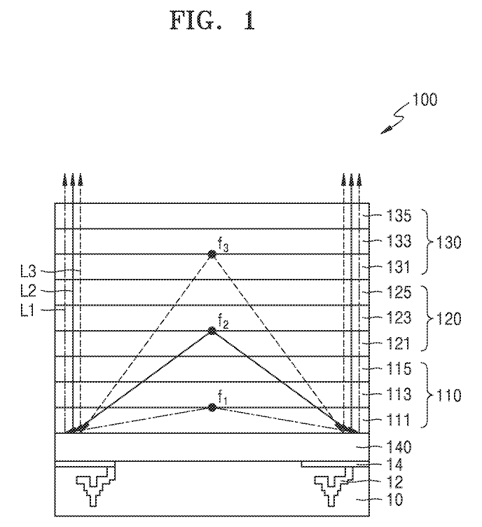

FIG. 1 is a cross-sectional view showing a display device according to one or more embodiments.

Referring to FIG. 1, a display device 100 may include a first lens 140 provided on a backplane substrate 10, and a first light-emitting element 110, a second light-emitting element 120, and a third light-emitting element 130, which are sequentially and monolithically stacked on the first lens 140.

The backplane substrate 10 may include at least one driving element 12. The at least one driving element 12 is configured to electrically drive the first light-emitting element 110, the second light-emitting element 120, and the third light-emitting element 130. The at least one driving element 12 may include, for example, a transistor, a thin film transistor, or a high electron mobility transistor (HEMT). However, the driving element 12 is not limited thereto and may further include, for example, a capacitor.

The backplane substrate 10 may include electrode pads 14 spaced apart from each other. The electrode pads 14 may be prepared for grounding or be connected to one of the at least one driving element 12 included in the backplane substrate 10. The electrode pad 14 may be connected to a driving element 12, for example, a drain of a transistor, provided on the backplane substrate 10 configured to drive, for example, the first light-emitting element 110, the second light-emitting element 120, and the third light-emitting element 130.

The first light-emitting element 110 may include a first semiconductor layer 111 of a first conductive type, an active layer 113, and a second semiconductor layer 115 of a second conductive type that are sequentially stacked. The first light-emitting element 110 may be, for example, configured to emit blue light.

The second light-emitting element 120 may include a first semiconductor layer 121 of a first conductive type, an active layer 123, and a second semiconductor layer 125 of a second conductive type that are sequentially stacked. The second light-emitting element 120 may be, for example, configured to emit green light.

The third light-emitting element 130 may include a first semiconductor layer 131 of a first conductive type, an active layer 133, and a second semiconductor layer 135 of a second conductive type that are sequentially stacked. The third light-emitting element 130 may be, for example, configured to emit red light.

The first semiconductor layers 111, 121, and 131 may be doped with the first conductivity type, while the second semiconductor layers 115, 125, and 135 may be doped with the second conductivity type that is electrically opposite to the first conductivity type. For example, the first semiconductor layers 111, 121 and 131 may be doped as n-type and the second semiconductor layers 115, 125, and 135 may be doped as p-type, or the first semiconductor layers 111, 121, and 131 may be doped as p-type and the second semiconductor layers 115, 125, and 135 may be doped as n-type. One of the first semiconductor layers 111, 121, and 131, and the second semiconductor layers 115, 125, and 135 may be a group III-V compound semiconductor layer doped as n-type, while another may be a group III-V compound semiconductor layer doped as p-type.

The active layers 113, 123, and 133 recombine electrons and holes provided from the first semiconductor layers 111, 121, and 131 and the second semiconductor layers 115, 125, and 135 to generate light. The active layers 113, 123, and 133 may have a quantum well structure, where the quantum well is placed between barriers. The wavelength of light generated in the active layers 113, 123, and 133 may be determined depending on the energy band gap of the material forming the quantum well in these active layers 113, 123, and 133. The active layers 113, 123, and 133 may have one quantum well, but may also have a multi-quantum well (MQW) structure with multiple quantum wells arranged therein. The energy of the quantum well in the conduction band may be set to be lower than the energy of the barrier. The barrier and quantum well within the active layers 113, 123, and 133 may include different compound semiconductors or compound semiconductors having different compositions.

The first semiconductor layers 111, 121, and 131, the active layers 113, 123, and 133, and the second semiconductor layers 115, 125, and 135 may include, for example, the group III-V compound semiconductor based on gallium nitride (GaN). For example, the first semiconductor layers 111, 121, and 131, the active layers 113, 123, and 133, and the second semiconductor layers 115, 125, and 135 may include the group III-V group compound semiconductor such as GaN, indium gallium nitride (InGaN), aluminum indium gallium nitride (AlInGaN), aluminum gallium indium phosphide (AlGaInP), etc., and the first semiconductor layers 111, 121, and 131 and the second semiconductor layers 115, 125, and 135 may be doped with opposite types to each other.

For example, the first semiconductor layers 111, 121, and 131 and the second semiconductor layers 115, 125, and 135 may contain GaN and be doped with opposite types. That is, the first semiconductor layers 111, 121, and 131 may include an n-type doped GaN layer, while the second semiconductor layers 115, 125, and 135 may include a p-type doped GaN layer. As another example, the first semiconductor layers 111, 121, and 131 may include an p-type doped GaN layer, while the second semiconductor layers 11dhs5, 125, and 135 may include a n-type doped GaN layer. The active layers 113, 123, and 133 may include, for example, InGaN and have different composition ratios of indium (In) and gallium (Ga) depending on the desired light emission wavelength.

In each of the first light-emitting element 110, the second light-emitting element 120, and the third light-emitting element 130, the active layers 113, 123, and 133 may have, for example, a stacked structure of a first barrier-quantum well-second barrier. The first barrier may be, for example, a GaN barrier that may be either Si-doped or undoped. The quantum well may have a single quantum well structure or multiple quantum well structures. For example, the quantum well may include a single stacked structure or multiple stacked structures such as InGaN/GaN or InGaN/GaN/AlGaN. In the stacked structure of InxGa1-xN that forms the quantum well, the composition ratio of In and Ga may vary depending on the emission wavelength. The GaN in the stacked structures that form quantum wells may either be Si-doped or undoped.

For example, when the first light-emitting element 110, the second light-emitting element 120, and the third light-emitting element 130 generate blue light, green light, and red light, respectively, the active layers 123 and 133 of the second and third light-emitting elements 120 and 130 may or may not include AlGaN, while the active layer 113 of the first light-emitting element 110 may not include AlGaN. For example, when the first light-emitting element 110, the second light-emitting element 120, and the third light-emitting element 130 generate blue light, green light, and red light, respectively, the active layers 123 and 133 of the second and third light-emitting elements 120 and 130, respectively, may or may not include AlGaN, while the active layer 113 of the first light-emitting element 110 may or may not include AlGaN.

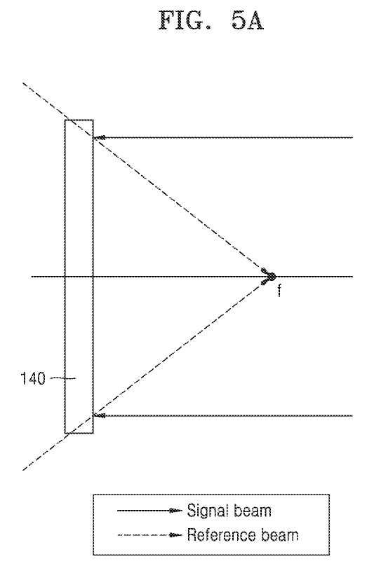

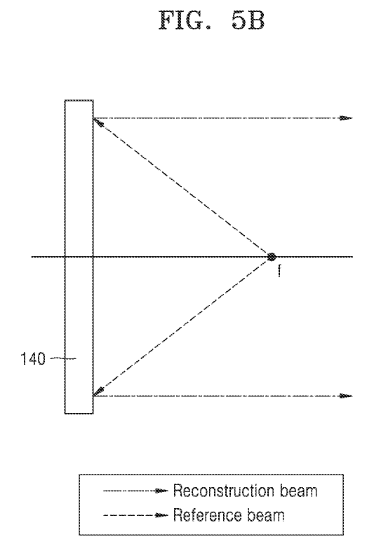

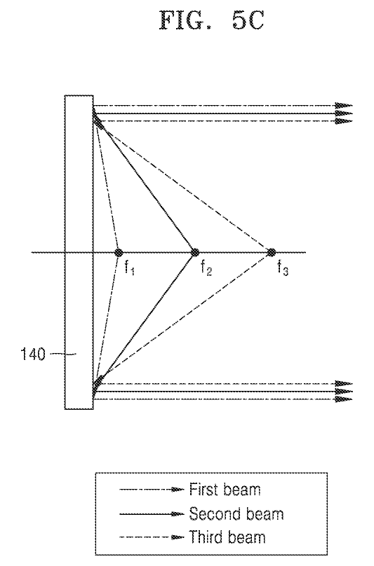

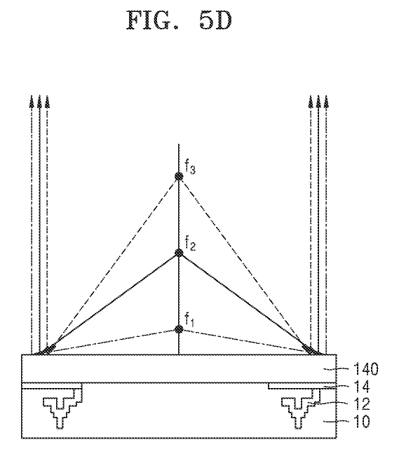

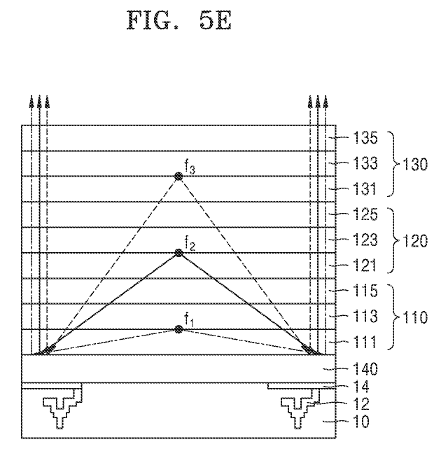

The first lens 140 may include a first interference pattern configured to reflect a first incident light L1 diverged from a first focal point f₁ located outside the first lens 140 and to convert the first incident light L1 into parallel light, a second interference pattern configured to reflect a second incident light L2 diverged from a second focal point f₂ located outside the first lens 140 and to convert the second incident light L2 into parallel light, and a third interference pattern configured to reflect a third incident light L3 diverged from a third focal point f₃ located outside the first lens 140 and to convert the third incident light L3 into parallel light. A method for having the first lens 140 include the interference pattern will be described later with reference to FIGS. 5A through 5C.

According to one or more embodiments, the first lens 140 may include a photopolymer. The photopolymer may include a first monomer responsive to red light, a second monomer responsive to green light, and a third monomer responsive to blue light. According to one or more embodiments, the first lens 140 may include a holographic lens. The thickness of the first lens 140 may be, for example, greater than or equal to 1 μm and less than or equal to 10 μm or less. The thickness of the first lens 140 may be, for example, greater than or equal to about 2 μm and less than or equal to 10 μm.

The first lens 140 may have multiple focal lengths that are different and focal points at different locations from each other by having different interference pattern periods for different wavelengths of light. The display device 100 may obtain the same parallel light from light sources at different locations through the first lens 140.

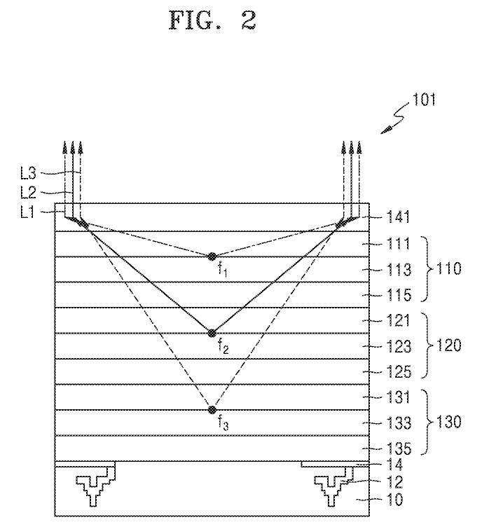

FIG. 2 is a cross-sectional view showing a display device according to one or more embodiments.

Referring to FIG. 2, the display device 101 may include a third light-emitting element 130, a second light-emitting element 120, and a first light-emitting element 110, which are stacked monolithically in sequence on the backplane substrate 10, and a first lens 141 disposed on the first light-emitting element 110. In describing FIG. 2, any details overlapping with FIG. 1 are omitted.

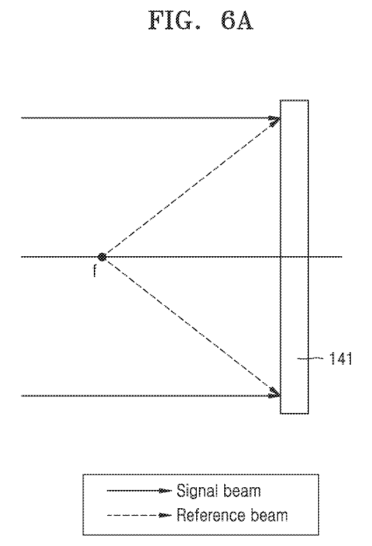

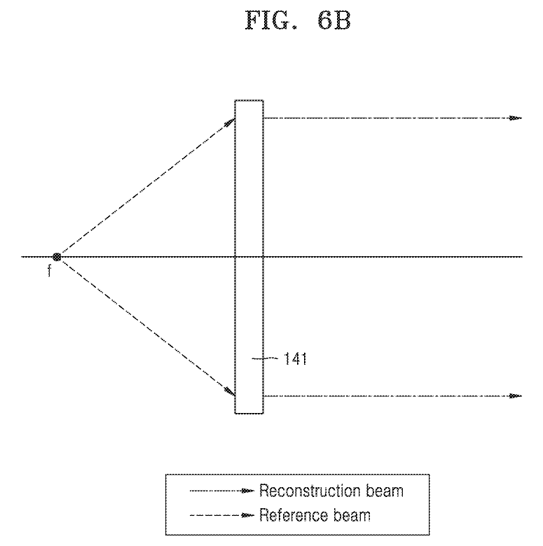

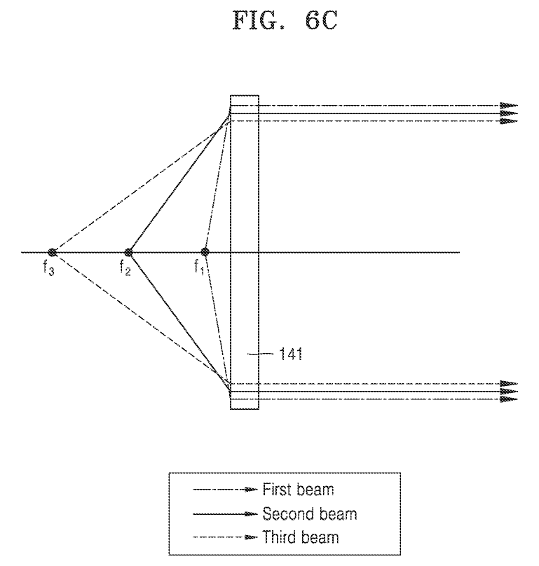

The first lens 141 may include a first interference pattern configured to diffract a first incident light L1 diverged from a first focal point f₁ located outside the first lens 141 and to convert the first incident light L1 into parallel light, a second interference pattern configured to diffract a second incident light L2 diverged from a second focal point f₂ located outside the first lens 141 and to convert the second incident light L2 into parallel light, and a third interference pattern configured to diffract a third incident light L3 diverged from a third focal point f₃ located outside the first lens 141 and to convert the third incident light L3 into parallel light. A method of having the first lens 140 include the interference pattern will be described later with reference to FIGS. 6A through 6C.

According to one or more embodiments, the first lens 141 may include a photopolymer. The photopolymer may include a first monomer responsive to red light, a second monomer responsive to green light, and a third monomer responsive to blue light. According to one or more embodiments, the first lens 141 may include a holographic lens. The thickness of the first lens 141 may be, for example, greater than or equal to 1 μm and less than or equal to 10 μm. The thickness of the first lens 141 may be, for example, about 2 μm to about 5 μm.

The first lens 141 may have multiple focal lengths that are different and focal points at different locations from each other by having different interference pattern periods for different wavelengths of light. The display device 101 may obtain the same parallel light from light sources at different locations through the first lens 141.

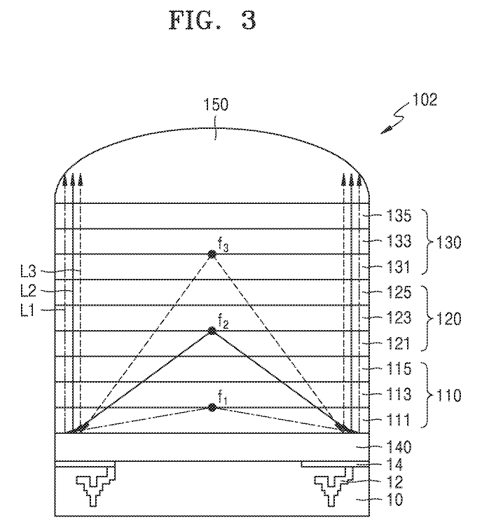

FIG. 3 is a cross-sectional view showing a display device according to one or more embodiments.

Referring to FIG. 3, the display device 102 may include a first lens 140 provided on a backplane substrate 10, and a first light-emitting element 110, a second light-emitting element 120, and a third light-emitting element 130, which are sequentially and monolithically stacked on the first lens 140.

The display device 102 may further include a second lens 150 provided on the third light emitting element 130 opposite to the second light-emitting element 120. The second lens 150 may be configured to reduce the angular distribution of light reflected by the first lens 140. The display device 102 may be identical to the display device 100 illustrated in FIG. 1, except that the display device 102 further includes a second lens 150. In describing FIG. 3, any details overlapping with FIG. 1 are omitted.

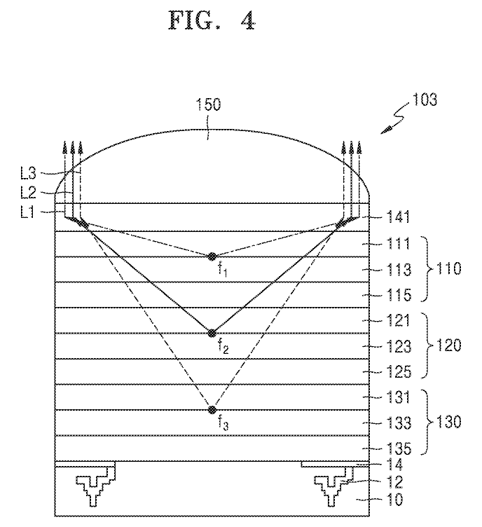

FIG. 4 is a cross-sectional view showing a display device according to one or more embodiments.

Referring to FIG. 4, the display device 103 may include a third light-emitting element 130, a second light-emitting element 120, and a first light-emitting element 110, which are stacked monolithically in sequence on the backplane substrate 10, and a first lens 141 disposed on the first light-emitting element 110.

The display device 103 may further include a second lens 150 disposed on the first lens 141. According to one or more embodiments, the second lens 150 may be configured to reduce the angular distribution of light diffracted by the first lens 141. The display device 103 may be identical to the display device 101 illustrated in FIG. 2, except that the display device further includes a second lens 150. In describing FIG. 4, any details overlapping with FIG. 2 are omitted.

FIGS. 5A to 5E are diagrams showing a method of manufacturing a display device, according to one or more embodiments.

The method of manufacturing a display device described with reference to FIGS. 5A to 5E may be a method of manufacturing the display device 100 of FIG. 1. In describing FIGS. 5A and 5B, any details overlapping with FIG. 1 are omitted.

Referring to FIG. 5A, the interference pattern is formed using a coherent beam. The interference pattern may be formed by interfering a signal beam incident parallel to the lens 140 from the right side of the lens 140 and a reference beam converging toward the focal point f from the left side of the lens 140. The reference beam may be generated using a microlens array.

Referring to FIG. 5B, the reference beam used to generate the interference pattern is incident on the lens 140 from the focal point f. The interference pattern formed inside the lens 140 diffracts the reference beam and changes the path of incident light, causing a reconstruction beam, derived from the incident light, to proceed parallel to the reflection direction.

Referring to FIG. 5C, by performing the method of forming an interference pattern, described with reference to FIGS. 5A and 5B, to collimate light diverged from the constant focal point f using red, green, and blue light, respectively, the single lens 140 with multiple different focal lengths may be formed.

The single lens 140 having the multiple different focal lengths may be manufactured through forming the first interference pattern that reflects the first incident light (first beam) that diverges from the first focal point f1 located outside the lens 140 and enters the lens 140 to create parallel light, the second interference pattern that reflects the second incident light (second beam) that diverges from the second focal point f2 located outside the lens 140 and enters the lens 140 to create parallel light, and the third interference pattern that reflects a third incident light (third beam) that diverges from a third focal point f3 located outside the lens 140 and enters the lens 140 to create parallel light. For example, one of the first incident light, the second incident light, and the third incident light may be red light, another may be green light, and the remaining one may be blue light.

Referring to FIGS. 5D and 5E, the lens 140 having multiple different focal lengths is attached to the backplane substrate 10. The first light-emitting element 110, the second light-emitting element 120, and the third light-emitting element 130 are sequentially and monolithically stacked on the lens 140, which is attached to the backplane substrate 10.

In a method of manufacturing the display device according to one or more embodiments, a reflective lens having multiple different focal lengths may be manufactured by forming multiple interference patterns that collimate light diverged from a constant focal point.

FIGS. 6A to 6C are cross-sectional views showing a method of manufacturing a lens, according to one or more embodiments.

A lens manufacturing method described with reference to FIGS. 6A to 6C may be the method of manufacturing the lens 141 of FIG. 2. In describing FIGS. 6A and 6C, any details overlapping with FIG. 2 are omitted.

Referring to FIG. 6A, an interference pattern is formed using a coherent beam. The interference pattern may be formed by interference between a signal beam incident in parallel to the lens 141 from the left side of the lens 141 and a reference beam diverging toward the lens 141 from a focal point f located on the left side of the lens 141. The reference beam may be generated using a microlens array.

Referring to FIG. 6B, the reference beam used to generate the interference pattern is incident on the lens 141 from the focal point f. The reference beam may be diffracted by the interference pattern formed inside the lens 141, changing the path of the incident light, so that the reconstructed beams propagate in parallel in the direction of passing through the lens 141.

Referring to FIG. 6C, by performing the method of forming an interference pattern, described with reference to FIGS. 6A and 6B, to collimate light diverged from the constant focal point f using red, green, and blue light, respectively, the single lens 141 with multiple different focal lengths may be manufactured.

The single lens 141 having the multiple different focal lengths may be manufactured through forming the first interference pattern that diffracts the first incident light that diverges from the first focal point f1 located outside the lens 141 and enters the lens 141 to create parallel light, the second interference pattern that diffracts the second incident light that diverges from the second focal point f2 located outside the lens 141 and enters the lens 141 to create parallel light, and the third interference pattern that diffracts a third incident light that diverges from a third focal point f3 located outside the lens 141 and enters the lens 141 to create parallel light. For example, one of the first incident light, the second incident light, and the third incident light may be red light, another may be green light, and the remaining one may be blue light.

In a method of manufacturing the lens according to one or more embodiments, a transmissive lens having multiple different focal lengths may be manufactured by forming multiple interference patterns that collimate light diverged from a constant focal point.

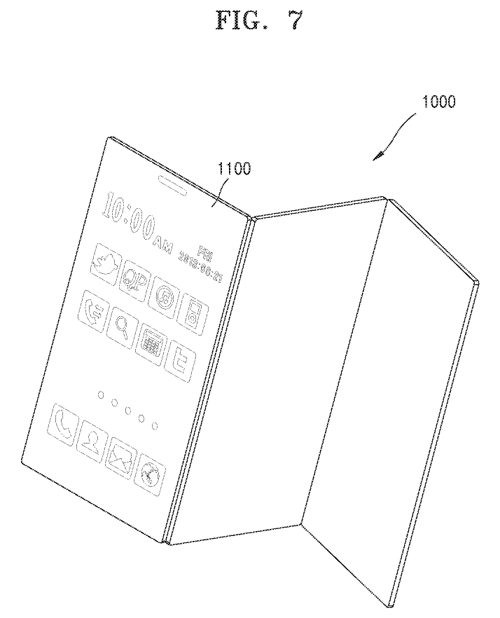

FIG. 7 illustrates an example in which a display device according to one or more embodiments is applied to a mobile device.

Referring to FIG. 7, the mobile device 1000 may include a display device 1100. The display device 1100 may include any one of the display devices 100, 101, 102, or 103 described in the foregoing embodiments. The display device 1100 may have a foldable structure and may be implemented, for example, as a multi-fold display. Although the mobile device 1000 is depicted here as having a foldable display, it is not limited thereto and the mobile device 1000 may also have, for example, a flat-panel display.

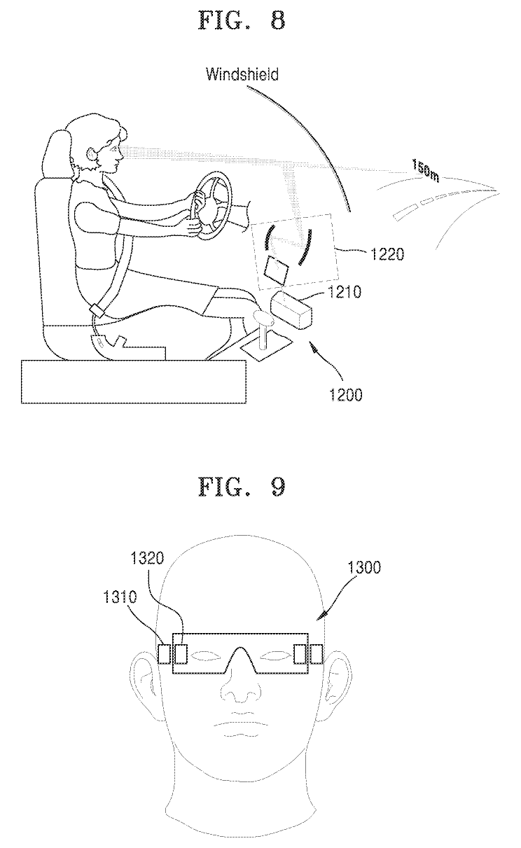

FIG. 8 illustrates an example of a display device according to one or more embodiments being applied to a vehicle display device.

Referring to FIG. 8, the display device may be a head-up display device 1200 for an automobile and may include a display 1210 installed in a specific area of the automobile, along with an optical path changing member 1220 that redirects the optical path, enabling the driver to view images generated by the display 1210. The display 1210 may include any one of the display devices 100, 101, 102, or 103 described in the foregoing embodiments.

FIG. 9 illustrates an example in which the display device according to one or more embodiments is applied to an augmented reality glass or a virtual reality glass.

Referring to FIG. 9, the augmented reality glasses 1300 may include a projection system 1310 that forms images and an element 1320 that guides the images from the projection system 1310 to the user’s eyes. The projection system 1310 may include any one of the display devices 100, 101, 102, or 103 described in the foregoing embodiments.

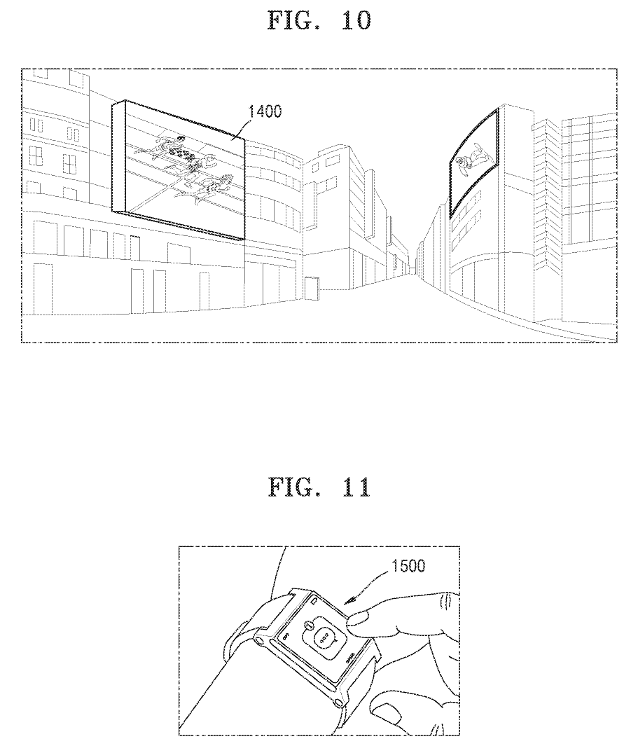

FIG. 10 illustrates an example in which a display device according to one or more embodiments is applied to signage.

Referring to FIG. 10, the signage 1400 may be used for, for example, outdoor advertising with a digital information display and may control advertising content and other information through a communication network. The signage 1400 may be implemented by applying one or more of the display devices 100, 101, 102, or 103 described in the foregoing embodiments.

FIG. 11 illustrates an example in which a display device according to one or more embodiments is applied to a wearable display.

Referring to FIG. 11, a wearable display 1510 may include any one of the display devices 100, 101, 102, or 103 described in the foregoing embodiments.

The display devices 100, 101, 102, and 103 according to the embodiments may also be applied to various products, such as rollable televisions (TVs) and stretchable displays.

According to the display device and the method of manufacturing the display device according to one or more embodiments, a display device and its manufacturing method may be provided, including multiple lenses with different focal lengths formed by multiple interference patterns. Although the display device and the method of manufacturing the display device have been described with reference to the embodiments illustrated in the drawings, these are merely examples, and those skilled in the art will understand that various modifications and equivalent embodiments may be derived therefrom.

It should be understood that embodiments described herein should be considered in a descriptive sense only and not for purposes of limitation. Descriptions of features or aspects within each embodiment should typically be considered as available for other similar features or aspects in other embodiments. While embodiments have been described with reference to the figures, it will be understood by those of ordinary skill in the art that various changes in form and details may be made therein without departing from the spirit and scope as defined by the following claims and their equivalents.

What is claimed is:

1. A display device comprising:
a first light-emitting element;
a second light-emitting element on the first light-emitting element; and
a third light-emitting element on the second light-emitting element; and
a first lens provided below the first light-emitting element,
wherein each of the first light-emitting element, the second light-emitting element, and the third light-emitting element comprises a first semiconductor layer of a first conductive type, an active layer, and a second semiconductor layer of a second conductive type that are sequentially stacked, and
wherein the first lens comprises:
a first interference pattern configured to reflect first incident light, that diverges from a first focal point outside the first lens and enters the first lens, to form parallel light; and
a second interference pattern configured to reflect second incident light, that diverges from a second focal point outside the first lens and enters the first lens, to form parallel light.

2. The display device of claim 1, wherein the first lens further comprises:
a third interference pattern configured to reflect third incident light, that diverges from a third focal point outside the first lens and enters the first lens, to form parallel light.

3. The display device of claim 1, wherein the first lens comprises a photopolymer.

4. The display device of claim 3, wherein the photopolymer comprises a first monomer responsive to red light, a second monomer responsive to green light, and a third monomer responsive to blue light.

5. The display device of claim 1, wherein the first lens comprises a holographic lens.

6. The display device of claim 1, wherein a thickness of the first lens is 2 μm to 10 μm.

7. The display device of claim 1, further comprising a second lens on the third light-emitting element.

8. The display device of claim 7, wherein the second lens is configured to reduce angular distribution of light reflected by the first lens.

9. The display device of claim 1, further comprising a backplane substrate provided below the first lens and comprising at least one driving element.

10. A display device comprising:
a third light-emitting element;
a second light-emitting element on the third light-emitting element; and
a first light-emitting element on the second light-emitting element; and
a first lens provided above the first light-emitting element;
wherein each of the first light-emitting element, the second light-emitting element, and the third light-emitting element comprises a first semiconductor layer of a first conductive type, an active layer, and a second semiconductor layer of a second conductive type that are sequentially stacked, and
wherein the first lens comprises:
a first interference pattern configured to diffract first incident light, that diverges from a first focal point outside the first lens and enters the first lens, to form parallel light; and
a second interference pattern configured to diffract second incident light, that diverges from a second focal point outside the first lens and enters the first lens, to form parallel light.

11. The display device of claim 10, wherein the first lens further comprises:
a third interference pattern configured to diffract third incident light, that diverges from a third focal point outside the first lens and enters the first lens, to form parallel light.

12. The display device of claim 10, wherein the first lens comprises a photopolymer.

13. The display device of claim 12, wherein the photopolymer comprises a first monomer responsive to red light, a second monomer responsive to green light, and a third monomer responsive to blue light.

14. The display device of claim 10, wherein the first lens comprises a holographic lens.

15. The display device of claim 10, wherein a thickness of the first lens is 2 μm to 10 μm.

16. The display device of claim 10, further comprising a second lens on the first lens.

17. The display device of claim 16, wherein the second lens is configured to reduce angular distribution of light diffracted by the first lens.

18. The display device of claim 10, further comprising a backplane substrate on the third light-emitting element and comprising at least one driving element.

19. A method of manufacturing a display device, the method comprising:
forming, in a lens, a first interference pattern configured to reflect first incident light, that diverges from a first focal point outside the lens and enters the lens, to form parallel light;
forming, in the lens, a second interference pattern configured to reflect second incident light, that diverges from a second focal point outside the lens and enters the lens, to form parallel light;
providing the lens on a backplane substrate;
providing a first light-emitting element on the lens;
providing a second light-emitting element on the first light-emitting element; and
providing a third light-emitting element on the second light-emitting element.

20. The method of claim 19, further comprising forming, in the lens, a third interference pattern configured to reflect third incident light, that diverges from a third focal point outside the lens and enters the lens, to form parallel light.
